(19) United States
(12) Patent Application Publication
(10) Pub. No.: US 2014/0345665 A1
(43) Pub. Date: Nov. 27, 2014

(54) THERMOELECTRIC ELEMENT HAVING STRUCTURE CAPABLE OF IMPROVING THERMAL EFFICIENCY

(71) Applicants: Woo Chul Kim, Seoul (KR); Sung Geun Park, Chuncheon-si (KR); Hoon Kim, Changwon-si (KR); Chan Young Kang, Seoul (KR)

(72) Inventors: Woo Chul Kim, Seoul (KR); Sung Geun Park, Chuncheon-si (KR); Hoon Kim, Changwon-si (KR); Chan Young Kang, Seoul (KR)

(73) Assignee: Industry-Academic Cooperation Foundation, Yonsei University, Seoul (KR)

(21) Appl. No.: 14/370,985

(22) PCT Filed: Aug. 8, 2012
(86) PCT No.: PCT/KR2012/006281

§ 371 Date: Jul. 8, 2014

(30) Foreign Application Priority Data
Jan. 30, 2012 (KR) 10-2012-0008810

(51) Int. Cl. H01L 35/32

(52) U.S. Cl. CPC H01L 35/32
USPC 136/205

(57) ABSTRACT

A thermoelectric device provided according to one aspect of the present invention includes a support member having a shape corresponding to a waste heat environment having a curved surface, and a thermoelectric material formed on a surface of the support member so that it surrounds the support member, wherein the support member is formed of a material having a low thermal conductivity, which is not the thermoelectric material, so as to keep a temperature difference between both ends of the thermoelectric device.

### TECHNICAL FIELD

The present invention relates to a thermoelectric device, and more particularly, to a thermoelectric device having a structure capable of easily recovering electricity from waste heat environments.

### BACKGROUND ART

A thermoelectric device is classified as one type of energy harvesting apparatuses. In general, the thermoelectric device includes a heat source, a heat absorption source (heat sink) and a thermopile. The thermopile consists of a plurality of thermocouples connected in series and is used to convert a part of the thermal energy into energy.

In general, the thermoelectric device is formed using semiconductor materials. The semiconductor materials are electrically connected in series and are thermally connected in parallel so as to form a thermocouple, thereby forming two junctions. The semiconductor materials include N-type and P-type materials. In a typical thermoelectric device, an electrically conductive connection is formed between the P-type and N-type materials, and carriers are moved from a hot junction to a cold junction resulting from the thermal diffusion, thereby inducing the current.

In order to use a thermoelectric device for a portable electronic device, the thermoelectric device is provided in a flexible form (for example, refer to Korean Patent Application Publication No. 10-2011-73166). The suggested thermoelectric device has a technical meaning, in that it is provided in a flexible form so as to appropriately apply the same to the portable electronic device. However, a configuration enabling the thermoelectric device to be used in waste heat environments where the thermoelectric device is used in many cases is not disclosed.

Specifically, a main application of the thermoelectric device is to recover the electricity from the waste heat to be wasted. In order to generate the electricity by using the thermoelectric device from the thermal energy, it is necessarily required to implement a high Seebeck constant and a high temperature difference. According to the thermoelectric device of the related art, a method of increasing a thickness of the thermoelectric device so as to implement the sufficient temperature difference is adopted.

However, according to the method of thickening the thermoelectric device, (1) it is difficult to realize a predetermined temperature or higher due to the heat and electrical resistance of a thermoelectric material and (2) the material is wasted.

Also, it is difficult to apply the thermoelectric device to the waste heat environments. That is, a representative environment where the waste heat is generated may be a chimney of a factory, for example. The chimney is formed to have a round shape, i.e., a curved shape. Therefore, the thick thermoelectric device cannot contact a round surface of the chimney over an entire surface thereof, so that there is a limit to recover the electricity from the waste heat. Regarding this, if the thermoelectric device is flexibly configured, as suggested in the above patent publication, it may be possible to apply the thermoelectric device to the waste heat environments such as the chimney. However, the flexible configuration of the thermoelectric device means that a thickness in a thickness direction of the thermoelectric device is extremely thinner, as compared to a longitudinal direction. In this case, a temperature difference between a part contacting the chimney surface of a high temperature and an opposite part thereto cannot be kept, so that the thermoelectric device cannot function as an efficient thermoelectric device.

### DISCLOSURE

### Technical Problem

The present invention has been made to solve the foregoing problems with the related art and an object of the invention is to provide a thermoelectric device having a structure that can be applied to a special environment such as waste heat environments.

Another object of the invention is to provide a thermoelectric device having a structure capable of increasing thermal efficiency and power to be generated even with a thermoelectric material of the related art.

A further object of the invention is to provide a thermoelectric device where not only a substrate of the thermoelectric device but the thermoelectric device is configured to be entirely flexible and where a structure capable of keeping a sufficient temperature difference even though a thickness of the thermoelectric device is sufficiently thin is provided.

### Technical Solution

In order to realize the foregoing object, according to the present invention, provided is a thermoelectric device including a support member having a shape corresponding to a waste heat environment having a curved surface, and a thermoelectric material formed on a surface of the support member so that it surrounds the support member, wherein the support member is formed of a material having a low thermal conductivity, which is not the thermoelectric material, so as to keep a temperature difference between both ends of the thermoelectric device.

In one embodiment, the thermoelectric material may consist of an inorganic material or organic material.

In one embodiment, the support member may be made of acryl.

In one embodiment, the thermoelectric material may be formed on the surface of the support member by an MOCVD (Metal-Organic Chemical Vapor Deposition), an ECVD (Electrochemical Vapor Deposition) or sputtering.

According to another aspect of the invention, provided is a power generation apparatus generating electricity by using a thermoelectric device. The thermoelectric device includes a support member having a shape corresponding to a waste heat environment having a curved surface, and a thermoelectric material formed on a surface of the support member so that it surrounds the support member. The support member is formed of a material having a low thermal conductivity, which is not the thermoelectric material, so as to keep a temperature difference between both ends of the thermoelectric device. A conducting wire drawn out from an electrode of the thermoelectric device is connected to the apparatus.

In one embodiment, the thermoelectric material may consists of an inorganic material or organic material, and the support member may be made of acryl.

In one embodiment, the thermoelectric material may be formed on the surface of the support member by an MOCVD, an ECVD or sputtering.

According to another aspect of the invention, provided is a thermoelectric device including two substrates made of a flexible material, and an electrode and a thermoelectric material provided between the two substrate, wherein a support member supporting the substrates is provided in a space, which is formed as the substrates are bent so that one of the flexible substrates faces each other, and fixed to the corresponding substrate, and wherein the thermoelectric device can be bent in conformity to a waste heat environment having a curved surface and the support member has a shape conforming to the curved surface.

In one embodiment, the support member may be formed of a material having a low thermal conductivity, which is not the thermoelectric material, for example, acryl.

In one embodiment, the thermoelectric material may be formed of an organic material, for example, a mixture of PEDOT:PSS and CNT.

### Advantageous Effects

According to the thermoelectric device of the present invention, the support member having a shape corresponding to a waste heat environment having a curved surface shape is beforehand configured and the thermoelectric material is formed on a surface of the support member so that it surrounds the support member. According to this configuration, it is possible to configure the thermoelectric device more variously, without a particular limit, and to apply the thermoelectric device without limitations on the waste heat environments.

Also, according to the thermoelectric device provided in accordance with another illustrative embodiment of the present invention, the thermoelectric material is formed of the organic material, differently from the related art, so that the thermoelectric device has flexibility enabling the device to be overall bent. Thereby, it is possible to easily apply the thermoelectric device to the waste heat environments having a curved surface, such as a chimney. Also, the substrates are bent so that one of the substrates faces each other and then the support member having a low thermal conductivity is fixed therebetween. Therefore, a sufficient temperature difference is kept between a heat sink and a heat source, so that the thermoelectric device can effectively exhibit a function thereof.

### DESCRIPTION OF DRAWINGS

FIG. 1 is a pictorial view schematically illustrating a configuration of a thermoelectric device that can be adopted in a first illustrative embodiment of the present invention.

FIG. 2 is a view showing a thermoelectric device actually manufactured according to the first illustrative embodiment of the present invention, in which it can be seen that the thermoelectric device has flexibility enough to bend a substrate to face each other.

FIG. 3 is a view illustrating a configuration of the thermoelectric device including a support member according to the first illustrative embodiment of the present invention, which pictorially shows that a sufficient temperature difference is kept between a heat source and a heat sink by the support member having a low thermal conductivity.

FIG. 4 shows a thermoelectric device including the support member actually manufactured according to the first illustrative embodiment of the present invention.

FIG. 5 shows that power is generated using the thermoelectric device manufactured according to the first illustrative embodiment of the present invention, in which it can be seen that the power is generated in proportional to a temperature difference while keeping the temperature difference.

FIG. 6 schematically illustrates configurations of a thermoelectric device according to a second illustrative embodiment of the present invention and a thermoelectric device of the related art.

FIG. 7 compares efficiencies depending on heats of the thermoelectric device according to the second illustrative embodiment of the present invention and the thermoelectric device of the related art.

### BEST MODE

Reference will now be made in detail to various embodiments of the present invention, examples of which are illustrated in the accompanying drawings and described below. In the following description of the present invention, detailed descriptions of known functions and components incorporated herein will be omitted. However, a person having ordinary skill in the art will be able to clearly comprehend the characteristic features and effects of the invention in light of the following embodiments and realize the present invention with no special difficulties.

### First Illustrative Embodiment

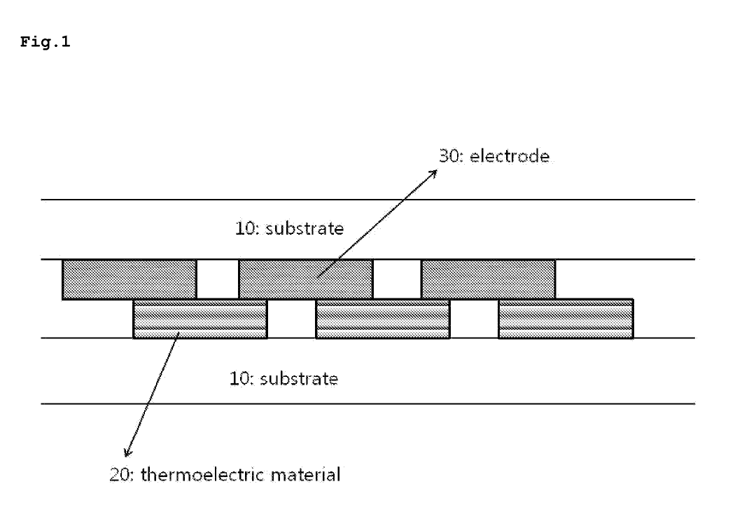

FIG. 1 is a schematic sectional view illustrating a configuration of a thermoelectric device that can be adopted in a first illustrative embodiment of the present invention.

As shown in FIG. 1, the thermoelectric device generally includes upper and lower substrates 10 and a plurality of thermoelectric material members 20 and electrodes 30 arranged therebetween. In the present invention, both the substrates 10 are formed of a flexible material such as PDMA, PMMA and PET.

Also, contrary to a thermoelectric device of the related art, the thermoelectric material member 20 is formed of an organic material. That is, according to the thermoelectric device of the related art, the thermoelectric material member is typically made of an inorganic material. However, according to this configuration, even though the substrates 10 are made of a flexible material, it is not possible to flexibly configure the thermoelectric device as a whole due to the thermoelectric material members. In contrast, according to the present invention, the thermoelectric material member 20 is made of a material obtained by mixing PEDOT:PSS and CNT, for example, so that the thermoelectric device is configured to be overall bent. In the meantime, the electrode 30 is made of aluminum.

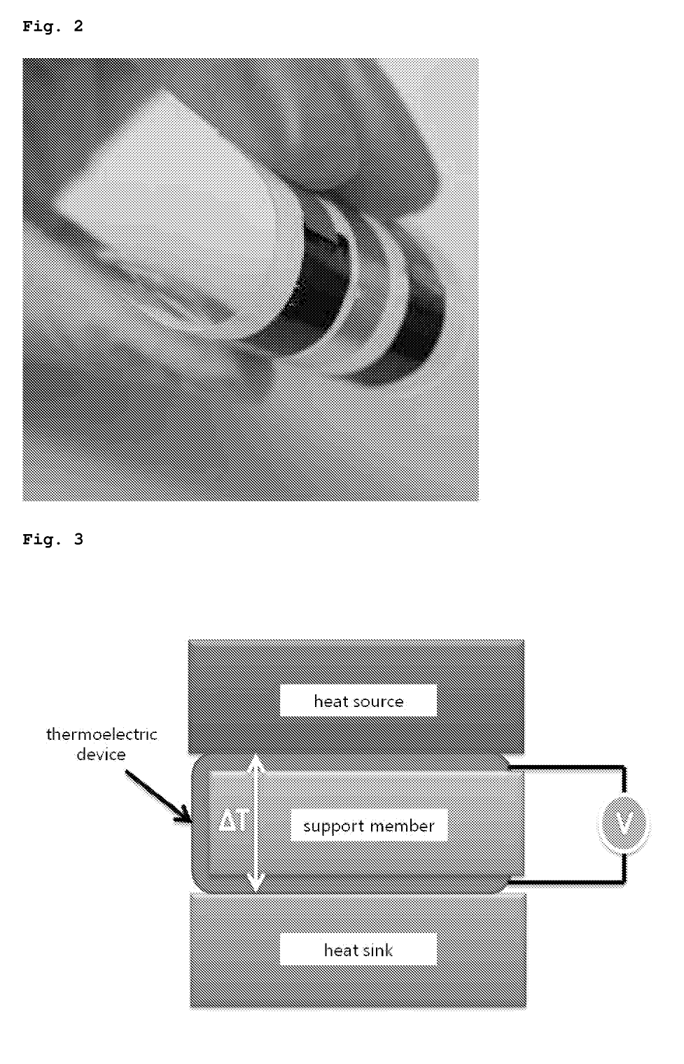

A thermoelectric device actually manufactured using the above-described structure is shown in FIG. 2. As shown in FIG. 2, it can be seen that the thermoelectric device of the present invention is configured to be very flexible as a whole (a thickness thereof is merely about 10 to 20 μm). That is, the thermoelectric device of the present invention has flexibility enough to bend a substrate to face each other.

In the meantime, as described in the Background Art, it is required to keep a sufficient temperature difference so that a thermoelectric device can effectively exhibit a function thereof. Regarding this, the thermoelectric device of the present invention as shown in FIG. 2 has an extremely thin thickness in a thickness direction thereof. Therefore, although the thermoelectric device can be easily applied to waste heat environments, for example, in a chimney having a round curved surface, a sufficient temperature difference is not kept via the thermoelectric device, so that the thermoelectric device cannot exhibit a function thereof.

Considering the above situation, the thermoelectric device of the present invention adopts a novel structure that has not been conventionally suggested. One illustrative embodiment thereof is pictorially shown in FIG. 3.

As shown in FIG. 3, the thermoelectric device of the present invention includes a support member 40 that is inserted in a space formed between the facing substrate by bending the substrates so that one of the two substrates faces each other. That is, the support member 40 is attached to the facing substrate, so that the thermoelectric device can keep the sufficient temperature difference. At this time, the support member 40 is preferably made of a material (for example, acryl) having a thermal conductivity as low as possible so that the thermal conduction transferred in the thickness direction of the thermoelectric device is minimized to keep the temperature difference.

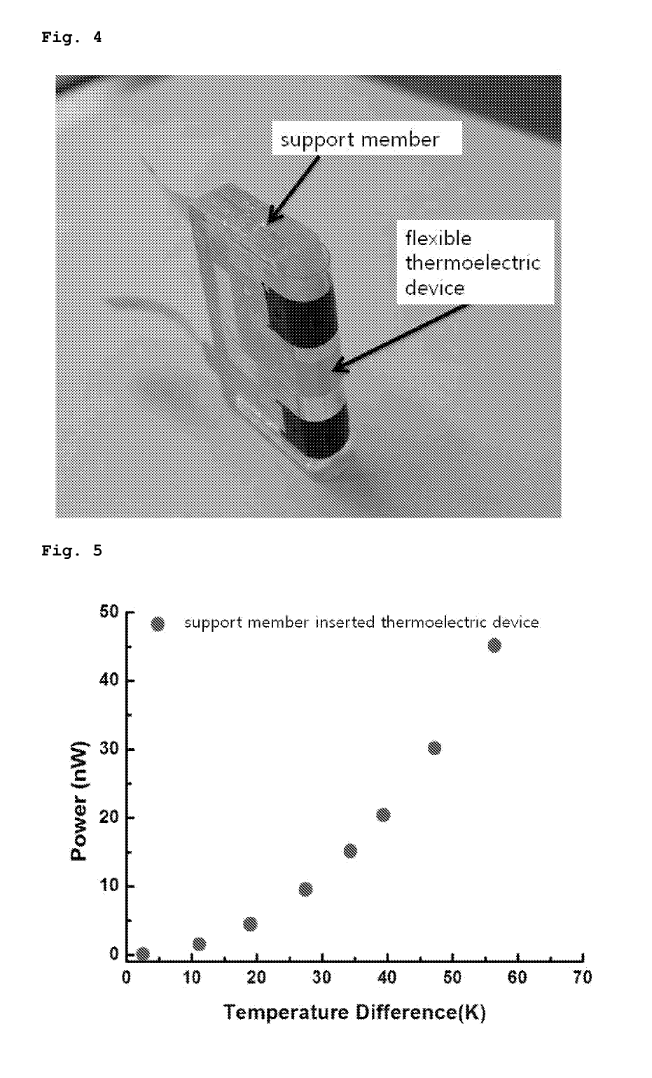

The thermoelectric device configured as described above can be applied to a variety of applications without limitations on the environments. That is, the thermoelectric device except for the support member 40 has the flexibility enabling the thermoelectric device to be easily bent, so that it can be easily mounted on a surface of the chimney from which the waste heat is generated. When a shape of the support member is beforehand designed in conformity to the curved surface of the chimney and is attached between the facing substrate of the thermoelectric device, it is possible to keep the sufficient temperature difference, so that the function of the thermoelectric device can be exhibited. That is, the curved surface of the chimney is a heat source from which the waste heat is generated. When the thermoelectric device of the present invention is mounted on the surface of the chimney, a temperature difference is kept between the heat source and a heat sink (atmosphere) owing to the support member 40 of the thermoelectric device. Therefore, when an electrode of the thermoelectric device is connected to a generator or storage battery, it is possible to effectively use the electricity generated from the thermoelectric device. That is, the thermoelectric device of the related art should be manufactured to be thick in the thickness direction of the device so as to keep the temperature difference, so that it cannot be applied to the waste heat environments such as the chimney. In contrast, a shape of the thermoelectric device of the present invention can be freely changed in conformity to the curved surface and the sufficient temperature difference can be kept between a part contacting the heat source and a part exposed to the atmosphere, so that the thermoelectric device can be applied to the various applications without limitations on the environments. In the meantime, FIG. 4 shows a configuration of the thermoelectric device including the support member 40 actually manufactured according to the first illustrative embodiment of the present invention.

The inventors performed a test so as to confirm whether the electricity can be actually generated using the thermoelectric device configured as described above. At this time, the heat source was the heating by a heater and the heat sink was the atmosphere. A testing result is shown in FIG. 5. As shown, it can be seen that the power is generated in proportional to a temperature difference (a difference of heating temperatures by the heater) while keeping the temperature difference. That is, it was confirmed that the function of the thermoelectric device is effectively exhibited.

### Second Illustrative Embodiment

In the above illustrative embodiment, after the thermoelectric device is configured to be flexible and is bent, the support member is inserted therebetween. However, the present invention is not limited thereto.

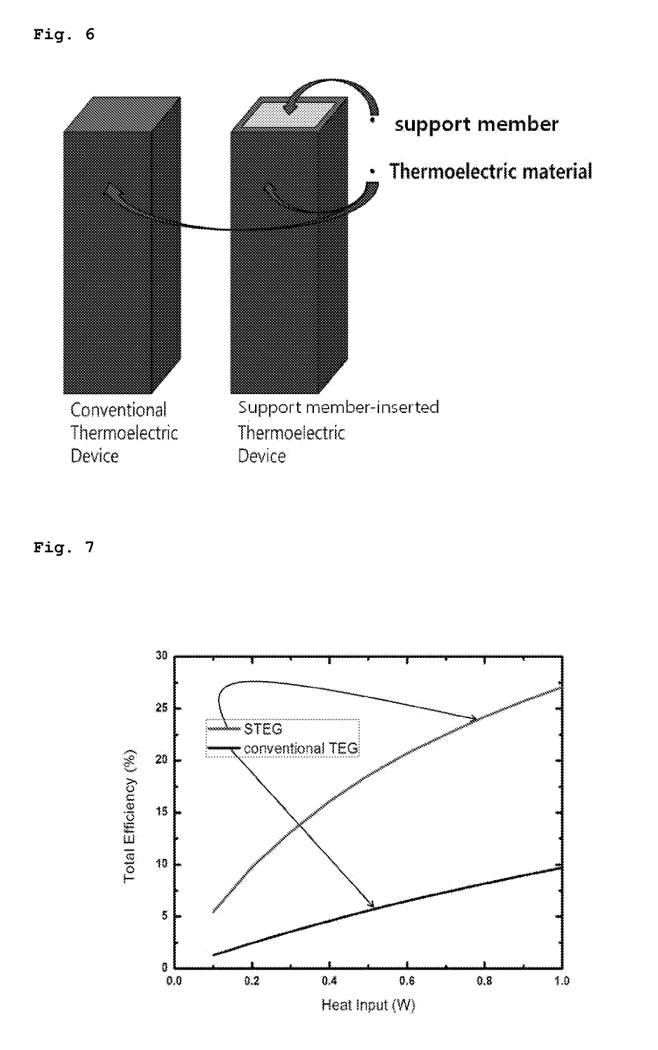

Specifically, FIG. 6 schematically illustrates configurations of a thermoelectric device according to a second illustrative embodiment of the present invention and a thermoelectric device of the related art.

As shown, the thermoelectric device of the related art is configured in a manner of increasing a thickness of the thermoelectric device so as to realize a sufficient temperature difference. However, according to this manner, the thermoelectric material should be much consumed and it is difficult to apply the thermoelectric device to the waste heat environments. That is, most of the waste heat environments include a part having a predetermined curvature, so that it is difficult to apply the thickened thermoelectric device in conformity to the curvature.

However, the present invention solves the above problems, breaking from the idea of the related art of increasing the thickness so as to realize the sufficient temperature difference. That is, as shown in FIG. 6, a thermoelectric device according to a second illustrative embodiment of the present invention includes a support member that is inserted in a hollow space in a center of the device, and configures a thermoelectric material and an electrode in a shape of surrounding the support member, and the support member is formed of a material that is not the thermoelectric material and has a low thermal conductivity. At this time, compared to the first illustrative embodiment, the thermoelectric device can be configured in more various aspects.

That is, according to the first illustrative embodiment, in order to flexibly configure the thermoelectric device except for the support member, the thermoelectric material is formed of the organic material and the substrates are formed of the flexible material, which is a limitation on the material. However, this illustrative embodiment can be more variously applied than the first illustrative embodiment because there is no limitation on the material. Specifically, according to this illustrative embodiment, when a shape of a support member is configured in conformity to an environment where the thermoelectric device is applied and then the thermoelectric material and the electrode are configured on a surface of the support member according to the method of the related art, the thermoelectric device can be simply configured. For example, the thermoelectric material can be configured on a surface of a support member having a predetermined shape by using an MOCVD (Metal-Organic Chemical Vapor Deposition), an ECVD (Electrochemical Vapor Deposition) or sputtering, which are used when manufacturing a semiconductor device. According to the thermoelectric device of this illustrative embodiment configured in this way, even when the thermoelectric material and electrode (the thermoelectric device members) except for the support member are made to be sufficiently thin, since it is possible to keep the sufficient temperature difference by the support member, the thermoelectric device can be applied without the limitation on the environments. That is, the support member can be made of a material having a low thermal conductivity, for example, acryl, a ceramic having a low thermal conductivity, and the like. At this time, when the thermoelectric device is applied to a part having a curvature, like the chimney, if the support member is manufactured to just conform to the curvature, the thermoelectric material and the like have the sufficiently small thickness, so that the thermoelectric device can be easily applied to the environment. Therefore, it is possible to apply the thermoelectric device without a limitation on the environments.

FIG. 7 is a graph of comparing efficiencies depending on heats of the thermoelectric device according to the second illustrative embodiment of the present invention and the thermoelectric device of the related art. That is, a thermoelectric device (STEG) where a size of the support member is about 5×5×10 mm and BiTe, which is a representative thermoelectric material, surrounds a periphery of the support member (at this time, as described above, BiTe may be formed using the MOCVD, ECVD or sputtering method) and a thermoelectric device of the related art having the same size and made of only the BiTe (p-type) material are compared in terms of the efficiency.

As can be seen from FIG. 7, the thermoelectric device of the present invention has the higher efficiency than that of the thermoelectric device of the related art. The efficiency is highly increased because the temperature difference between both ends of the device is increased due to the low thermal conductivity of the support member. That is, since the thermal conductivity of the support member is lower than the thermal conductivity of the thermoelectric material surrounding the support member, the heat is not transferred well, so that it is possible to make the higher temperature difference with the same heat source, thereby highly improving the efficiency.

Although the invention has been described hereinabove with respect to the certain illustrative embodiments, it should be understood that the invention is not limited to the foregoing illustrative embodiments. That is, the present invention can be variously modified and changed within the scope of the appended claims, and such modifications and changes fall within the scope of the invention. Therefore, it should be understood that the scope of the invention shall be defined only by the appended claims and the equivalents thereof.

1. A thermoelectric device comprising:
a supporting structure having a shape adapted to a waste heat environment including a curved surface, and
a thermoelectric material formed on the surface of the supporting structure so that it wraps around the supporting structure,
wherein the supporting structure is formed of a material having a low thermal conductivity, which is not the thermoelectric material, so as to keep a temperature difference between both ends of the thermoelectric device.

2. The thermoelectric device according to claim 1, wherein the thermoelectric material consists of an inorganic material or organic material.

3. The thermoelectric device according to claim 1, wherein the supporting structure is made of acryl.

4. The thermoelectric device according to claim 1, wherein the thermoelectric material is formed on the surface of the supporting structure by an MOCVD (Metal-Organic Chemical Vapor Deposition), an ECVD (Electrochemical Vapor Deposition) or sputtering.

5. A power generation apparatus generating electricity by using a thermoelectric device,
wherein the thermoelectric device comprises a supporting structure having a shape adapted to a waste heat environment including a curved surface, and a thermoelectric material formed on a surface of the supporting structure so that it surrounds the supporting structure, the supporting structure being formed of a material having a low thermal conductivity, which is not the thermoelectric material, so as to keep a temperature difference between both ends of the thermoelectric device, and
wherein a conducting wire drawn out from an electrode of the thermoelectric device is connected to the apparatus.

6. The power generation apparatus according to claim 5, wherein the thermoelectric material consists of an inorganic material or organic material.

7. The power generation apparatus according to claim 5, wherein the supporting structure is made of acryl.

8. The power generation apparatus according to claim 5, wherein the thermoelectric material is formed on the surface of the supporting structure by an MOCVD (Metal-Organic Chemical Vapor Deposition), an ECVD (Electrochemical Vapor Deposition) or sputtering.

9. A thermoelectric device comprising:
two substrates made of a flexible material, and
an electrode and a thermoelectric material provided between the two substrates,
wherein a supporting structure supporting the substrates is provided in a space, which is formed as the substrates are bent so that one of the flexible substrates faces each other, and fixed to the corresponding substrate, and
wherein the thermoelectric device can be bent in conformity to a waste heat environment including a curved surface and the supporting structure has a shape conforming to the curved surface.

10. The thermoelectric device according to claim 9, wherein the supporting structure is formed of a material having a low thermal conductivity, which is not the thermoelectric material.

11. The thermoelectric device according to claim 10, wherein the supporting structure is made of acryl.

12. The thermoelectric device according to claim 10, wherein the thermoelectric material is formed of an organic material.

13. The thermoelectric device according to claim 12, wherein the thermoelectric material is formed of a mixture of PEDOT:PSS and CNT.
